(19) United States
(12) Patent Application Publication
(10) Pub. No.: US 2013/0299346 A1
(43) Pub. Date: Nov. 14, 2013

(54) SPUTTERING DEVICE WITH A TUBULAR TARGET

(71) Applicants: Armin Huebner, Dresden (DE); Hans-Juergen Heinrich, Grossroehrsdorf (DE)

(72) Inventors: Armin Huebner, Dresden (DE); Hans-Juergen Heinrich, Grossroehrsdorf (DE)

(73) Assignee: VON ARDENNE ANLAGENTECHNIK GMBH, Dresden (DE)

(21) Appl. No.: 13/817,982

(22) PCT Filed: Aug. 24, 2011
(86) PCT No.: PCT/EP11/64559

§ 371 Date: Apr. 24, 2013

(30) Foreign Application Priority Data
Sep. 3, 2010 (DE) 10 2010 040 267.2

(51) Int. Cl. C23C 14/34

(52) U.S. Cl. CPC C23C 14/3407
USPC 204/298.12

(57) ABSTRACT

A sputtering device with a tubular target, includes a holding device with a supporting shaft having a shaft flange connected to the target tube detachably and in a water-tight manner by a clamping device. The end of the target tube facing the shaft flange of the supporting shaft is flangeless and a spacer ring is arranged detachably on the outer side of the tube in a predetermined position. The spacer ring is held by a form-fitting connection at a minimum distance from the end of the target tube. The clamping device includes the shaft flange of the supporting shaft, the spacer ring and a clamping ring which engages over the shaft flange and the spacer ring and comprises at least two pieces. At least one sealing element is arranged between the outer side and/or the end side of the target tube, and an opposite sealing face of the shaft flange.

The invention relates to a sputtering device with a tubular target according to the preamble of claim 1, such as are used in substrate treatment plants.

It is customary inside vacuum process chambers to have tube connections in order to connect subassemblies to one another and at the same time seal them off by means of integrated seals. Basically, two media have to be separated from one another reliably, for example cooling water inside the pipe and the vacuum prevailing in the inner space of the vacuum process chamber, that is to say outside the pipe.

One example of tube connections of this type is the attachment of a tubular target to the holder of a sputtering device. Holders of this type may be designed, for example, as what are known as end blocks.

The tubular target is usually fastened in a cantilever manner in the vacuum chamber of a vacuum coating plant to one end block or between two end blocks designed such that they in each case allow the rotatable mounting of the tubular target. Mostly, in this case, the two end blocks perform different functions. One of the end blocks may be designed as a supply end block for supplying the magnetron with cooling water and electrical energy and the other end block as a drive end block for introducing a torque to generate the rotation of the tubular target, although combined supply and drive end blocks are also known. Examples of end blocks of this type are known from the patent applications EP 1 365 436 A2 and DE 10 2007 049 735 A1.

The cooling medium located inside the tubular target should be incapable of generating process-damaging leakage to the vacuum. As a consequence of the process, it is necessary to ensure that the target tube is supplied reliably with electrical energy via the tube connection. The clamping of the target should not have any electrically insulating effect. In order to carry out a stable vacuum process, the target tubes must be mounted accurately and process-damaging vibrations and asymmetries in the true running of the tubes must be prevented by radial centering.

The target tube is consumed as a consequence of the process and has to be renewed or exchanged during maintenance work, and in this case, with the vacuum chamber open, the end-face tube connections are opened and are closed again after the exchange. Tube connections requiring a large number of loose or filigree components in order to perform this task are counterproductive when the mounting sequences are simple to carry out. By contrast, structurally simple solutions for cost-effective connections conflict with the complicated manufacture of tubes with narrow tolerances which are necessary for this purpose.

Previous solutions for the clamping of tubes are based on protected sealing surfaces on the tube which are arranged on the inside of the tubes. It is state of the art, for example, to place a chamfer in the tube and accommodate the seal belonging to it on a flange, for example a carrying shaft belonging to a holder. The tube is centered via a centering collar of the flange, said centering collar also being supported on the inside diameter of the tube.

It is state of the art, furthermore, to integrate seals directly into a flange and to weld the latter to the tube. Moreover, it is known that tube clamping with a union flange or clamping flange holds both components together and the electrical energy flows via these. Such a solution is described, for example, in WO 2006/135528 A1.

The object on which the invention is based is to provide a tube connection which comprises few components and is simple to handle and which can be produced and assembled so as to be self-centering, coolant-tight and vacuum-tight and independently of restricting manufacturing tolerances of the semifinished tubes. The tube connection, moreover, should ensure better electrical contact between the target tube and the carrying shaft.

This object is achieved by means of a sputtering device having the features of patent claim 1. Advantageous refinements and developments are disclosed in the dependent claims and the following description.

A sputtering device for the tubular target is proposed, which comprises a holder with a carrying shaft which has a shaft flange which is releasably connected, water-tight, to a target tube by means of a clamping device, that end of the target tube which faces the shaft flange of the carrying shaft being flangeless, and a spacer ring being arranged releasably on its outside in a predetermined position and being held positively at a minimum distance from the end of the target tube, the clamping device being formed from the shaft flange of the carrying shaft, from the spacer ring and from a tension ring engaging over the shaft flange and the spacer ring and composed of at least two portions, and at least one sealing ring being arranged between the outside and/or the end face of the target tube, on the one hand, and an opposite sealing surface of the shaft flange, on the other hand.

In other words, the spacer ring is arranged releasably on the end of the target tube such that said spacer ring is positively prevented from displacement after the predetermined position in the axial direction of the target tube at least toward to the end of the target tube. This can be achieved in various ways, as explained in more detail below. By the minimum distance of the spacer ring from the end face of the target tube and therefore from a shaft flange of the carrying shaft being fixed positively, a welded-on flange may be dispensed with. Just a few individual parts are sufficient to make a highly accurate and leak-tight connection between the target tube and carrying shaft. The spacer ring, which is coupled firmly to the carrying shaft by the clamping device, can be plugged on in a simple way and likewise be removed again in a simple way. At the same time, the proposed solution achieves improved electrical contacting between the target tube and the carrying shaft.

According to a further feature of the proposed solution, the leak tightness of the connection is achieved by means of a sealing ring which is arranged on the outside or on the end face of the target tube and which cooperates with a correspondingly designed sealing surface of the shaft flange of the carrying shaft. Such a sealing surface on the shaft flange may be, for example, a planar surface, but also a groove, for example a groove into which the target tube can be plugged. In this case, the sealing ring may be arranged between the end face of the target tube and the groove bottom in the shaft flange or between a groove formed on the outside of the target tube and the groove flank in the shaft flange.

The spacer ring and/or the shaft flange may have on the surfaces pointing away from one another a conical surface which matches with conical inner surfaces of the clamping ring, so that the spacer ring and the shaft flange are pulled toward one another by the clamping ring. At the same time, the clamping ring, which, like the shaft flange and the spacer ring, is manufactured from a metallic material, serves as a current bridge in order to make a conductive connection.

As already stated above, the positive fixing of the minimum distance of the spacer ring from the end face of the target tube may be achieved in various ways, some of which are described below. However, these refinements are purely by way of example and should in no way be interpreted restrictively.

In a first refinement, that end of the target tube which faces the shaft flange of the carrying shaft has at least one annular groove on its outside, wherein the spacer ring is composed of at least two portions and engages on its inside into the annular groove, and the spacer ring is held at a minimum distance from the end of the target tube by the annular groove. In this refinement, the spacer ring is fixed in the groove and consequently in the predetermined position without further aids. However, the spacer ring must in this case be divided so that it can be attached to the target tube.

In a second refinement, that end of the target tube which faces the shaft flange of the carrying shaft has on its outside at least one annular groove and a sealing ring which is arranged in the annular groove and the outside diameter of which is larger than the outside diameter of the target tube, so that the spacer ring is held at a minimum distance from the end of the target tube by the sealing ring. In this refinement, the sealing ring serves at the same time for fixing the position of the spacer ring, that is to say for ensuring the minimum distance between the spacer ring and shaft flange, and in this case the spacer ring and/or the shaft flange may have a conical sealing surface bearing against the sealing ring.

In a third refinement, that end of the target tube which faces the shaft flange of the carrying shaft has on its outside at least one annular groove and a stop ring which is arranged in the annular groove and the outside diameter of which is larger than the outside diameter of the target tube, so that the spacer ring is held at a minimum distance from the end of the target tube by the stop ring. In this refinement, the stop ring, which may be, for example, a spring ring, that is to say an elastic metal ring with an interruption, serves for fixing the position of the spacer ring, that is to say for ensuring the minimum distance between the spacer ring and shaft flange, and in this case the sealing ring may be attached in another position, for example in a dedicated groove on the outside of the target tube, or on the end face of the target tube.

As already indicated above, there may be provision, further, whereby at least one surface, touched by the sealing ring, of the shaft flange and/or of the spacer ring and/or of the target tube is conical. Self-centering of the target tube with respect to the shaft flange can thereby be achieved by simple means, while at the same time an enlarged sealing surface is available.

Finally, it is proposed that the target tube have on its end face a narrow region with a reduced outside diameter, into which the sealing ring is inserted. In this case, furthermore, a pressure ring, which ensures a uniform distribution of pressure to the sealing ring, may be arranged on the region with a reduced outside diameter.

The invention is explained in more detail below by means of exemplary embodiments and accompanying drawings in which:

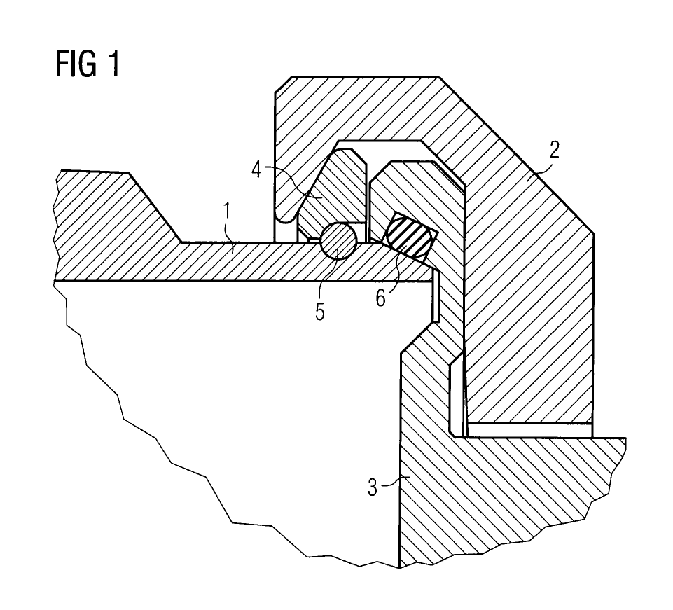

FIG. 1 shows a first exemplary embodiment,

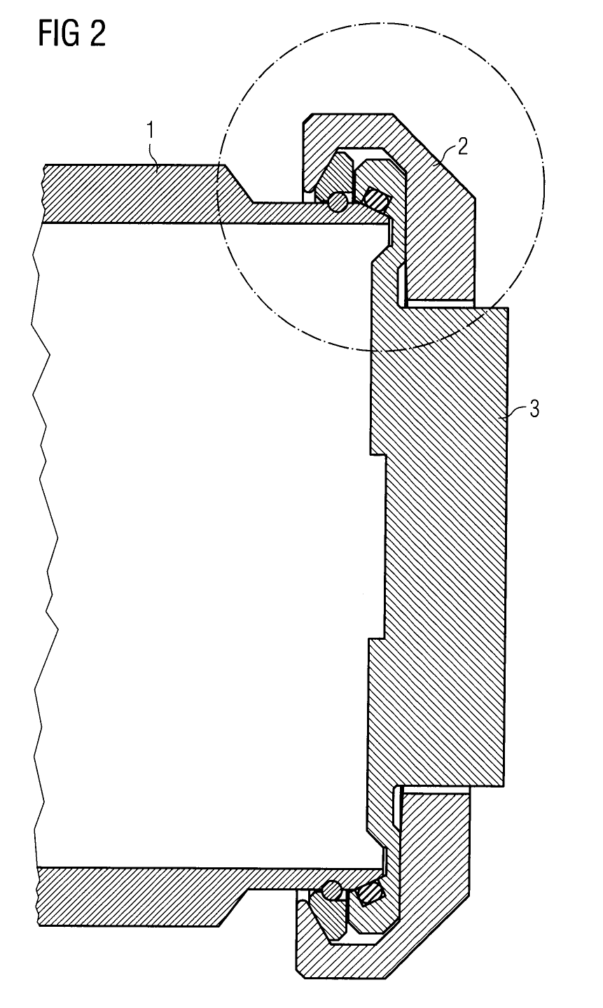

FIG. 2 shows an overall view of the tube connection with identification of the region illustrated in FIG. 1,

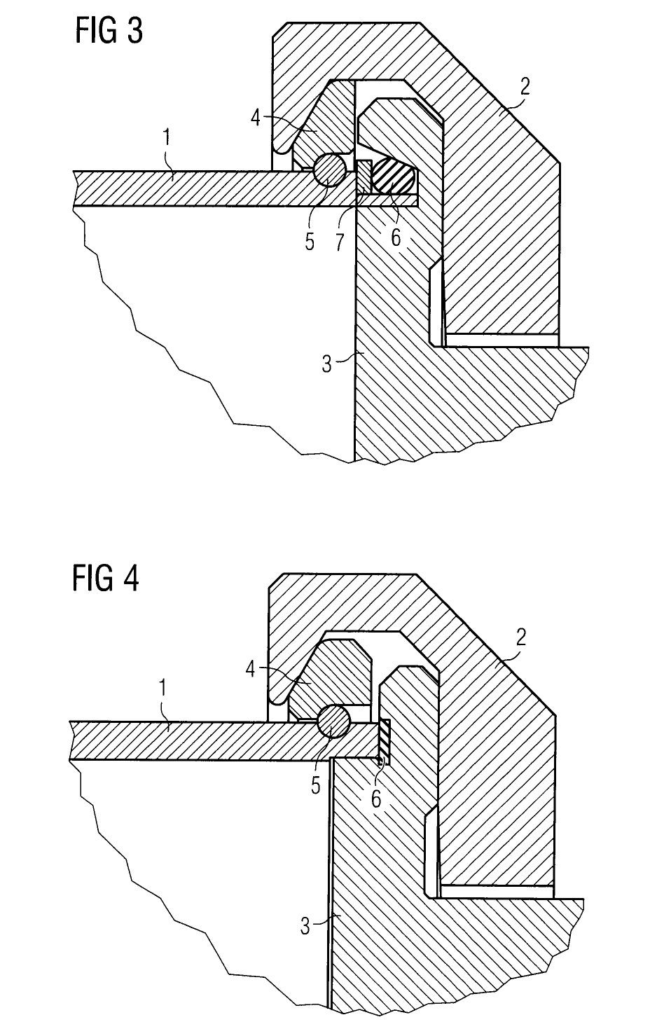

FIG. 3 shows a second exemplary embodiment,

FIG. 4 shows a third exemplary embodiment,

FIG. 5 shows a fourth exemplary embodiment,

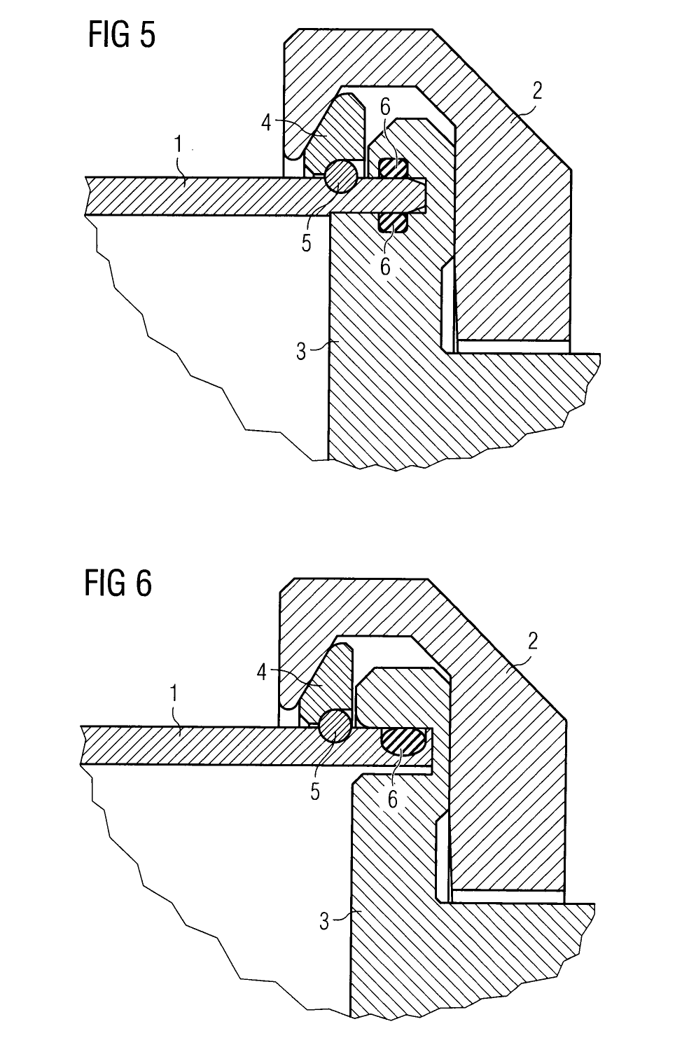

FIG. 6 shows a fifth exemplary embodiment,

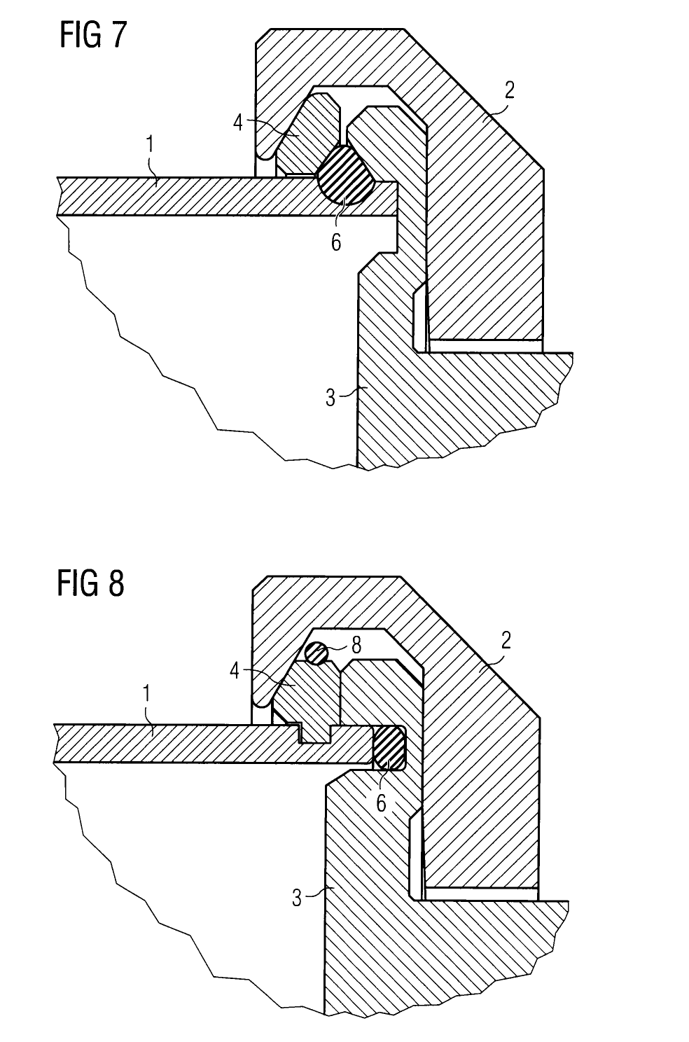

FIG. 7 shows a sixth exemplary embodiment, and

FIG. 8 shows a seventh exemplary embodiment.

In the exemplary embodiment of FIGS. 1 and 2, a connection of a target tube 1 to the shaft flange 3 of a carrying shaft of a holder is illustrated. In this case, FIG. 2 shows the overall connection location, while FIG. 1 illustrates this in detail.

That end of the target tube 1 which faces the shaft flange 3 of the carrying shaft has no flange. A spacer ring 4 is arranged releasably on its outside in a predetermined position and is held positively at a minimum distance from the end of the target tube. For this purpose, that end of the target tube 1 which faces the shaft flange 3 of the carrying shaft has on its outside an annular groove and a stop ring 5, in the exemplary embodiment a spring ring made from spring steel, which is arranged in the annular groove and the outside diameter of which is larger than the outside diameter of the target tube 1. The spacer ring 4 is held at a minimum distance from the end of the target tube by the stop ring.

The spacer ring 4 and the shaft flange 3 are connected to one another by a tension ring 2 which engages over the shaft flange 3 and the spacer ring 4 and which is composed of two portions. The spacer ring 4 and the shaft flange 3 have conical surfaces on their respective outsides. The tension ring 2 has on its inside conical surfaces matching therewith, so that the spacer ring 4 and the shaft flange 3 are pulled toward one another by the tension ring 2.

A sealing ring 6 is arranged between the outside of the target tube 1, said outside being designed conically in the exemplary embodiment, and an opposite sealing surface of the shaft flange 3, said sealing surface being designed here as a groove in the conical surface of the shaft flange 3.

In the exemplary embodiment according to FIG. 3, by contrast, a groove is arranged in a surface of the shaft flange 3, said surface being oriented perpendicularly to the axis of the target tube 1, and the end of the target tube is arranged in this groove. This end of the target tube 1 has on its end face a narrow region with a reduced outside diameter, into which the sealing ring 6 is inserted. Moreover, a pressure ring 7 is arranged on the region with a reduced outside diameter and ensures a uniform distribution of pressure to the sealing ring 6.

In the exemplary embodiment according to FIG. 4, the sealing ring 6 is arranged in front of the planar end face of the target tube 1.

In the exemplary embodiment according to FIG. 5, a groove, in which the end of the target tube 1 is arranged, is arranged in a surface of a shaft flange 3, said surface being oriented perpendicularly to the axis of the target tube 1. Sealing rings 6 are arranged in a groove in each case on the inside and the outside of the target tube 1 and bear sealingly against the groove flanks in the shaft flange 3.

In the exemplary embodiment according to FIG. 6, by contrast, a sealing ring 6 is arranged in a groove only on the outside of the target tube 1 and bears sealingly against the groove flank in the shaft flange 3.

In the exemplary embodiment according to FIG. 7, that end of the target tube 1 which faces the shaft flange 3 of the carrying shaft has on its outside an annular groove and a sealing ring 6 which is arranged in the annular groove and the outside diameter of which is larger than the outside diameter of the target tube. The spacer ring 4 is thereby held at a minimum distance from the end of the target tube 1 by the sealing ring 6.

In the exemplary embodiment according to FIG. 8, that end of the target tube 1 which faces the shaft flange 3 of the carrying shaft has an annular groove on its outside. The spacer ring 4 is composed of two portions and engages on its inside into the annular groove. The two portions of the spacer ring 4 are held together by a spring ring 8. The spacer ring 4 is held at a minimum distance from the end of the target tube 1 by the annular groove.

### LIST OF REFERENCE SYMBOLS

1 Target tube
2 Clamping ring
3 Shaft flange
4 Spacer ring
5 Stop ring
6 Sealing ring
7 Pressure ring
8 Spring ring

1. A sputtering device with a tubular target, comprising a holder with a carrying shaft which has a shaft flange releasably connected, water-tight, to the target tube by a clamping device,
an end of the target tube which faces the shaft flange of the carrying shaft being flangeless, and a spacer ring being arranged releasably on an outside of the target tube in a predetermined position and being held positively at a minimum distance from the end of the target tube,
the clamping device comprising the shaft flange of the carrying shaft, the spacer ring and a tension ring engaging over the shaft flange and the spacer ring and composed of at least two portions, and
at least one sealing ring being arranged between the outside and/or an end face of the target tube, and an opposite sealing surface of the shaft flange.

2. The sputtering device as claimed in claim 1, wherein the end of the target tube which faces the shaft flange of the carrying shaft has at least one annular groove on the outside of the tubular target, an inside of the spacer ring engages into the annular groove, and the spacer ring is held at the minimum distance from the end of the target tube by the annular groove.

3. The sputtering device as claimed in claim 1, wherein the end of the target tube which faces the shaft flange of the carrying shaft has on the outside of the tubular target at least one annular groove and a sealing ring arranged in the annular groove, an outside diameter of the sealing ring is larger than an outside diameter of the target tube, and the spacer ring is held at the minimum distance from the end of the target tube by the sealing ring.

4. The sputtering device as claimed in claim 1, wherein the end of the target tube which faces the shaft flange of the carrying shaft has on an outside of the tubular target at least one annular groove and a stop ring arranged in the annular groove, an outside diameter of the stop ring is larger than an outside diameter of the target tube, and the spacer ring is held at the minimum distance from the end of the target tube by the stop ring.

5. The sputtering device as claimed in claim 1, at least one surface, touched by the sealing ring, of the shaft flange and/or of the spacer ring and/or of the target tube is conical.

6. The sputtering device as claimed in claim 1, wherein the target tube has on the end face a narrow region with a reduced outside diameter, and the sealing ring is inserted into the narrow region.
